(19) United States
(12) Patent Application Publication
(10) Pub. No.: US 2020/0294567 A1
(43) Pub. Date: Sep. 17, 2020

(54) MAGNETORESISTIVE ELEMENT AND MAGNETIC MEMORY DEVICE

(71) Applicant: TOSHIBA MEMORY CORPORATION, Tokyo (JP)

(72) Inventors: Tadaaki OIKAWA, Seoul (KR); Young Min EEH, Seongnam-si Gyeonggi-do (KR); Kazuya SAWADA, Seoul (KR); Kenichi YOSHINO, Seongnam-si Gyeonggi-do (KR); Eiji KITAGAWA, Seoul (KR); Taiga ISODA, Seoul (KR)

(73) Assignee: TOSHIBA MEMORY CORPORATION, Tokyo (JP)

(21) Appl. No.: 16/568,123

(22) Filed: Sep. 11, 2019

(30) Foreign Application Priority Data
Mar. 15, 2019 (JP) 2019-048662

(51) Int. Cl. G11C 11/16; H01L 43/10; H01L 43/08; H01L 27/22

(52) U.S. Cl. CPC G11C 11/161; H01L 27/226; H01L 43/08; H01L 43/10

(57) ABSTRACT

According to one embodiment, a magnetoresistive element includes a first magnetic layer having an invariable magnetization direction; a non-magnetic layer provided on the first magnetic layer; a second magnetic layer provided on the non-magnetic layer, having an invariable magnetization direction, and containing a rare-earth element; a third magnetic layer provided on the second magnetic layer and composed of cobalt; and an oxide layer provided on the third magnetic layer.

### CROSS-REFERENCE TO RELATED APPLICATIONS

This application is based upon and claims the benefit of priority from prior Japanese Patent Application No. 2019-048662, filed Mar. 15, 2019, the entire contents of which are incorporated herein by reference.

### FIELD

An embodiment described herein relates to a magnetoresistive element and a magnetic memory device.

### BACKGROUND

Magnetoresistive random-access memory (MRAM) is known as a type of semiconductor memory device. MRAM is a memory device that uses magnetoresistive elements, which have a magnetoresistive effect, in memory cells that store information. Spin-injection write technique is one of the writing techniques in MRAM. The spin-injection write technique is advantageous for high integration, low power consumption, and high performance, since the spin injection current required to reverse the magnetization decreases as the size of the magnetic body decreases.

### BRIEF DESCRIPTION OF THE DRAWINGS

FIG. 1 is a cross-sectional view of an MTJ element 10 according to the first embodiment.

FIG. 2 is a schematic diagram illustrating magnetic characteristics of a ferromagnetic layer to which a non-magnetic element is added.

FIG. 3 is a schematic diagram illustrating magnetic characteristics of a ferromagnetic layer to which another non-magnetic element is added.

FIG. 4 is a schematic diagram illustrating magnetic characteristics of a. ferromagnetic layer to which a rare-earth element is added.

FIG. 5 is a table illustrating characteristics of Comparative Examples 1-6 and Examples 1-3.

FIG. 6 is a cross-sectional view illustrating a stacked structure of Comparative Examples 1 and 2.

FIG. 7 is a cross-sectional view illustrating a stacked structure of Comparative Example 3.

FIG. 8 is a cross-sectional view illustrating a stacked structure of Comparative Examples 4-6.

FIG. 9 is a cross-sectional view illustrating a stacked structure of Examples 1-3.

FIG. 10 is a block diagram of an MRAM 100 according to the second embodiment.

FIG. 11 is a cross-sectional view of the MRAM 100 according to the second embodiment.

### DETAILED DESCRIPTION

In generally, according to one embodiment, a magnetoresistive element includes a first magnetic layer having an invariable magnetization direction; a non-magnetic layer provided on the first magnetic layer; a second magnetic layer provided on the non-magnetic layer, having an invariable magnetization direction, and containing a rare-earth element; a third magnetic layer provided on the second magnetic layer and composed of cobalt; and an oxide layer provided on the third magnetic layer.

Hereinafter, embodiments will be described with reference to the accompanying drawings. In the description that follows, components having the same functions and configurations will be denoted by the same reference symbols, and repeated descriptions will be given only where necessary. The drawings are schematic or conceptual, and the dimensions and ratios, etc. in the drawings are not always the same as the actual ones. The embodiments serve to give examples of apparatuses and methods that realize the technical concepts of the embodiments. The technical ideas of the embodiments are not intended to limit the materials, shapes, structures, arrangements, etc. of the components to those described herein.

### First Embodiment

Hereinafter, a description will be given of a magnetoresistive element included in a magnetoresistive memory device. The magnetoresistive element is also called a magnetoresistive effect element, or a magnetic tunnel junction (MTJ) element. The magnetoresistive memory device (magnetic memory) is a magnetoresistive random access memory (MRAM).

[1] Configuration of MTJ Element

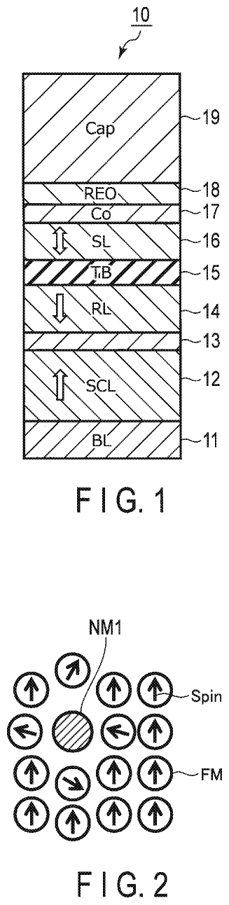

FIG. 1 is a cross-sectional view of an MTJ element 10 according to the first embodiment. The MTJ element 10 shown in FIG. 1 is provided on a foundation structure (unillustrated) including a substrate.

As illustrated in FIG. 1, the MTJ element 10 includes a buffer layer (BL) 11, a shift canceling layer (SGL) 12, a spacer layer 13, a reference layer (RL) 14, a tunnel barrier layer (TB) 15, a storage layer (SL) 16, a cobalt layer (also referred to as a “magnetic layer”) 17, an oxide layer (REO) 18, and a cap layer (Cap) 19, stacked in this order. The storage layer 16 is also referred to as a “free layer”. The reference layer 14 is also referred to as a “fixed layer”. The shift canceling layer 12 is also referred to as “a shift adjustment layer”. The planar shape of the MTJ element 10 is not particularly limited, and may be, for example, a circle or an oval.

The buffer layer 11 contains, for example, aluminum (Al), beryllium (Be), magnesium (Mg), calcium (Ca), strontium (Sr), barium (Ba), scandium (Sc), yttrium (Y), lanthanum (La), silicon (Si), zirconium (7,r), hafnium (Hf), tungsten (W), chromium (Cr), molybdenum (Mo), niobium (Nb), titanium (Ti), tantalum (Ta), or vanadium (V). The buffer layer 11 may contain a boride thereof. The boride is not limited to a binary compound consisting of two different elements, and may be a ternary compound consisting of three different elements. That is, the boride may be a mixture of binary compounds. For example, the buffer layer 11 may be composed of a hafnium boride (HfB), a magnesium aluminum boride (MgAlB), a hafnium aluminum boride (HfAlB), a scandium aluminum boride (ScAlB), a scandium hafnium boride (ScHfB), or a hafnium magnesium boride (HfMgB). The buffer layer 11 may be composed of more than one of these materials stacked upon one another. By using a high-melting-point metal or a boride thereof, it is possible to suppress diffusion of the material of the buffer layer into the magnetic layer, thereby preventing deterioration of the magnetoresistance (MR) ratio. The high-melting-point metal is a material having a melting point higher than iron (Fe) and cobalt (Co), and examples include zirconium (Zr), hafnium (Hf), tungsten (W), chromium (Cr), molybdenum (Mo), niobium (Nb), titanium (Ti), tantalum (Ta), and vanadium (V), as well as alloys thereof.

The shift canceling layer 12 has a function of reducing a leakage field from the reference layer 14, suppressing the reduced leakage field from being applied to the storage layer 16, and shifting the coercive force (or the magnetization curve) of the storage layer 16. The shift canceling layer 12 is composed of a ferromagnetic material. The shift canceling layer 12 has, for example, perpendicular magnetic anisotropy, and its easy magnetization direction is approximately perpendicular to the film surface. The expression “approximately perpendicular” means that the direction of the remanent magnetization is within the range of 45°<θ≤90°, with respect to the film surface. The magnetization direction of the shift canceling layer 12 is invariable and fixed to one direction. The magnetization directions of the shift canceling layer 12 and the reference layer 14 are set to be antiparallel. The shift canceling layer 12 is composed of, for example, the same ferromagnetic material as the reference layer 14. The material of the reference layer 14 will be described later. Of the ferromagnetic materials that will be listed as example materials of the reference layer 14, a material different from the reference layer 14 may be selected as the material of the shift canceling layer 12.

The spacer layer 13 is composed of a non-magnetic material, and has a function of antiferromagnetically bonding the reference layer 14 and the shift canceling layer 12. That is, the reference layer 14, the spacer layer 13, and the shift canceling layer 12 have a synthetic antiferromagnetic (SAF) structure. The reference layer 14 and the shift canceling layer 12 are antiferromagnetically bonded via the spacer layer 13. The spacer layer 13 is composed of, for example, ruthenium (Ru) or an alloy of ruthenium (Ru).

The reference layer 14 is composed of a ferromagnetic material. The reference layer 14 has, for example, perpendicular magnetic anisotropy, and its easy magnetization direction is approximately perpendicular to the film surface. The magnetization direction of the reference layer 14 is invariable and fixed to one direction. The “invariable” magnetization direction means that the magnetization direction of the reference layer 14 does not change when a predetermined write current is allowed to flow through the MTJ element 10.

The reference layer 14 is composed of a compound containing at least one of iron (Fe), cobalt (Co), and nickel (Ni). The reference layer 14 may further contain, as impurities, at least one of boron (B), phosphorus (P), carbon (C), aluminum (Al), silicon (Si), tantalum (Ta), molybdenum (Mo), chromium (Cr), hafnium (Hf) , tungsten (W), and titanium (Ti). More specifically, the reference layer 14 may contain, for example, a cobalt iron boron (CoFeB) or an iron boride (FeB). Alternatively, the reference layer 14 may contain at least one of cobalt platinum (Copt), cobalt nickel (Cori), and cobalt palladium (Coed).

The tunnel barrier layer 15 is composed of a non-magnetic material. The tunnel barrier layer 15 functions as a barrier between the reference layer 14 and the storage layer 16. The tunnel barrier layer 15 is composed of, for example, an insulating material, and contains, in particular, a magnesium oxide (MgO).

The storage layer 16 is composed of a ferromagnetic material. The storage layer 16 has, for example, perpendicular magnetic anisotropy, and its easy magnetization direction is perpendicular or approximately perpendicular to the film surface. The magnetization direction of the storage layer 16 is variable and reversible. The “variable” magnetization direction means that the magnetization direction of the storage layer 16 may change when a predetermined write current is allowed to flow through the MTJ element 10. The storage layer 16, the tunnel barrier layer 15, and the reference layer 14 form a magnetic tunnel junction. In FIG. 1, the magnetization directions of the storage layer 16, the reference layer 14, and the shift canceling layer 12 are denoted by arrows, as an example. The magnetization direction of each of the storage layer 16, the reference layer 14, and the shift canceling layer 12 is not limited to a perpendicular direction and may be an in-plane direction.

The storage layer 16 is composed of a compound containing a rare-earth element and at least one of iron (Fe), cobalt (Co), and nickel (Ni). Such a compound may further contain boron (B). In other words, the storage layer 16 may be composed of: Co and a rare-earth element; Fe and a rare-earth element; Ni and a rare-earth element; Co, Fe, and a rare-earth element; or one of these structures further containing B. The rare-earth elements include scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). Of these rare-earth elements, gadolinium (Gd), terbium (Tb), and dysprosium (Dy) are particularly effective.

The cobalt layer 17 is a magnetic layer consisting mainly of cobalt (Co). Specifically, the cobalt layer 17 is composed only of cobalt (Co). The cobalt layer 17 has a function of improving the magnetic characteristics of the storage layer 16.

The oxide layer 18 is composed of a metal oxide, and contains a rare-earth element (RE). An oxide of a rare-earth element is also simply called a rare-earth oxide (REO). Examples of the rare-earth element contained in the oxide layer 18 include scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). The rare-earth element contained in the oxide layer 18 has a crystal structure in which the lattice of bonding (e.g. covalent bonding) has a large spacing, as compared to the other elements. Accordingly, when a ferromagnetic layer adjacent to the oxide layer 18 contains impurities and is noncrystalline (amorphous), the oxide layer 18 has a function of diffusing the impurities into itself in a high-temperature environment (e.g., during an annealing process). That is, the oxide layer 18 has a function of removing impurities from an amorphous ferromagnetic layer through an annealing process, and making the ferromagnetic layer in a highly-oriented crystallized state.

The cap layer 19 is a non-magnetic conductive layer, and contains, for example, platinum (Pt), tungsten (W), tantalum (Ta), or ruthenium (Ru).

The MTJ element 10 is capable of rewriting data using, for example, the spin-injection write technique. In the spin-injection write technique, a write current is allowed to directly flow through the MTJ element 10, and the magnetization state of the MTJ element 10 is controlled by the write current. The MTJ element 10 may take either a low-resistance state or a high-resistance state, according to whether the relative relationship of magnetization between the storage layer 16 and the reference layer 14 is parallel or antiparallel. That is, the MTJ element 10 is a variable resistor element.

When a write current is allowed to flow through the MTJ element 10, from the storage layer 16 to the reference layer 14, the relative relationship of magnetization between the storage layer 16 and the reference layer 14 becomes parallel. In this parallel state, the MTJ element 10 has the lowest resistance value, and the MTJ element 10 is set to a low-resistance state. The low-resistance state of the MTJ element 10 is defined as, for example, data “0”.

On the other hand, when a write current is allowed to flow through the MTJ element 10, from the reference layer 14 to the storage layer 16, the relative relationship of magnetization between the storage layer 16 and the reference layer 14 becomes antiparallel. In this antiparallel state, the MTJ element 10 has the highest resistance value, and the MTJ element 10 is set to a high-resistance state. The high-resistance state of the MTJ element 10 is defined as, for example, data “1”.

This allows the MTJ element 10 to be used as a memory device capable of storing one-bit data (two-value data). The allocation of data to the resistance states of the MTJ element 10 may be suitably set.

When data is read from the MTJ element 10, a read voltage is applied to the MTJ element 10, and the resistance value of the MTJ element 10 is detected using a sense amplifier, etc., based on the read current flowing through the MTJ element 10 during the application of the read voltage. The read current is set to a value sufficiently lower than the threshold value at which the magnetization is reversed by spin injection.

[2] Structure of Storage Layer

Next, a description will be given of the structure of the storage layer. The storage layer is composed of a ferromagnetic layer.

To improve the write error rate (WER), it is desirable to decrease the saturation magnetization. Ms of the ferromagnetic layer. One way to decrease the saturation magnetization Ms is to add a non-magnetic element to the ferromagnetic layer.

FIG. 2 is a schematic diagram illustrating magnetic characteristics of a ferromagnetic layer to which a non-magnetic element is added. In the example of FIG. 2, a non-magnetic element having a relatively large mass is added to a ferromagnetic layer. Examples of the non-magnetic element having a relatively large mass include molybdenum (Mo), tungsten (W), and tantalum (Ta). The circles enclosing arrows shown in FIG. 2 represent a plurality of ferromagnetic particles FM forming the ferromagnetic layer. The arrows in the ferromagnetic particles represent spins. The hatched circle shown in FIG. 2 represents a non-magnetic element NM1.

The saturation magnetization Ms can be decreased in a ferromagnetic layer to which a non-magnetic element NM1 having a relatively large mass is added, as shown in FIG. 2. However, the spins are disordered in the periphery of the non-magnetic element NM1. This causes deterioration of the thermal stability Δ of the ferromagnetic layer. In an MTJ element to be subjected to a high-temperature heat treatment in the manufacturing process, deterioration of the thermal stability Δ of the ferromagnetic layer is not preferable.

The disorder of the spins of the ferromagnetic layer causes an increase in the damping coefficient α. Since the write current is proportional to the damping coefficient α, it is desirable that the damping coefficient a be small to reduce the current. Moreover, the disorder in the spins of the ferromagnetic layer causes a decrease in the exchange stiffness constant Aex. The exchange stiffness constant Aex is a measure of the intensity of exchange interaction between particles. The decrease in the exchange stiffness constant Aex of the ferromagnetic layer causes deterioration of the thermal stability L.

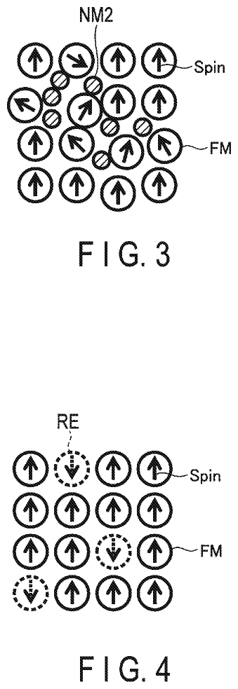

FIG. 3 is a schematic diagram illustrating magnetic characteristics of a ferromagnetic layer to which another non-magnetic element is added. In the example of FIG. 3, a non-magnetic element having a relatively small mass is added to a ferromagnetic layer. Examples of the non-magnetic element having a relatively small mass include boron (B). The hatched circles shown in FIG. 3 represent a non-magnetic element NM2.

The saturation magnetization Ms can be decreased in a ferromagnetic layer to which a non-magnetic element NM2 having a relatively small mass is added, as shown in FIG. 3. However, the spins are disordered in the periphery of the non-magnetic element NM2, as in FIG. 2. This causes an increase in the damping coefficient a and a decrease in the exchange stiffness constant Aex.

FIG. 4 is a schematic diagram illustrating magnetic characteristics of a ferromagnetic layer to which a rare-earth element is added. The dashed circles shown in FIG. 4 represent a rare-earth element RE.

As shown in FIG. 4, when a rare-earth element RE is added to a ferromagnetic layer, the magnetization direction of the rare-earth element RE becomes antiparallel to the magnetization direction of the ferromagnetic layer. That is, the rare-earth element RE is capable of partially canceling the saturation magnetization Ms of the ferromagnetic layer, thereby reducing the saturation magnetization Ms of the ferromagnetic layer.

In addition, since the rare-earth element RE and the ferromagnetic particles FM are magnetically bonded, the spins of the ferromagnetic layer are suppressed from being disordered. This suppresses a decrease in the exchange stiffness constant Aex of the ferromagnetic layer, thereby suppressing deterioration of the thermal stability Δ of the ferromagnetic layer. As the additive amount of the rare-earth element RE increases, the saturation magnetization Ms can be further decreased.

The storage layer 16 of the present embodiment has the configuration illustrated in. FIG. 4. A case will be described where the storage layer 16 is composed mainly of cobalt iron boron (CoFeB) to which a rare-earth element RE is added.

[3] Stacked Structure Including Storage Layer SL, Cobalt Layer Co, and Oxide Layer REO

Next, a description will be given of the stacked structure including the storage layer SL, the cobalt layer Co, and the oxide layer REO.

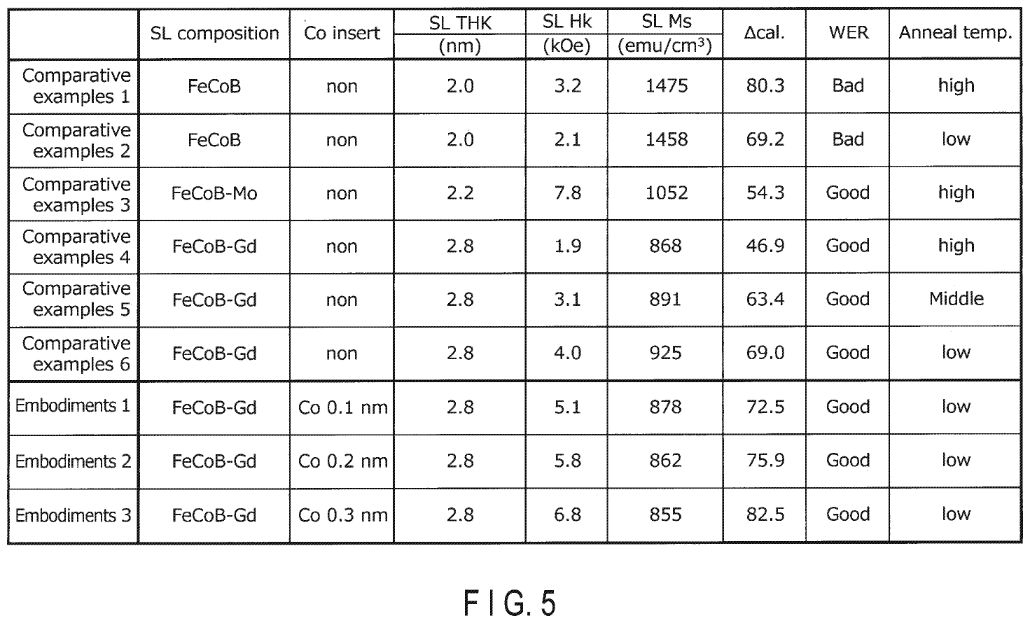

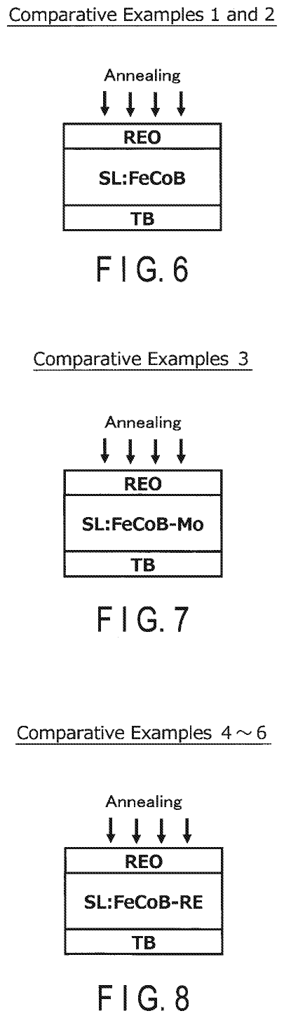

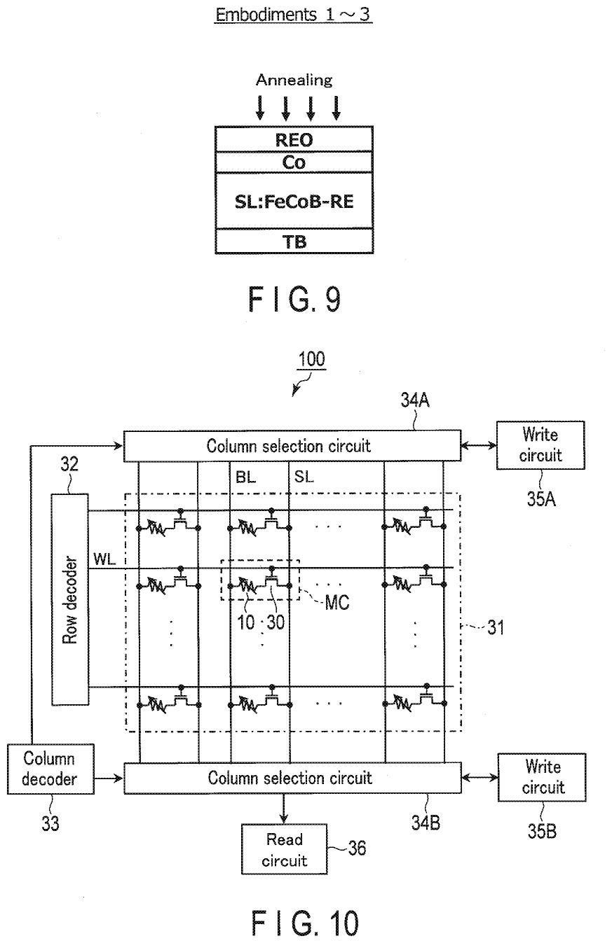

FIG. 5 is a table illustrating characteristics of Comparative Examples 1-6 and Examples 1-3. FIG. 6 is a cross-sectional view illustrating a stacked structure of Comparative Examples 1 and 2. FIG. 7 is a cross-sectional view illustrating a stacked structure of Comparative Example 3. FIG. 8 is a cross-sectional view illustrating a stacked structure of Comparative Examples 4-6. FIG. 9 is a cross-sectional view illustrating a stacked structure of Examples 1-3. In the cross-sectional views of FIGS. 6-9, the storage layer SL and its upper and lower layers are focused.

FIG. 5 illustrates the composition of the storage layer SL, the presence or absence of a cobalt layer Co, the thickness of the storage layer SL (nm), the anisotropy field Hk (kOe) of the storage layer SL, the saturation magnetization Ms (emu/cm³) of the storage layer SL, the calculated value of the thermal stability Δ, the write error rate WER, and the annealing temperature. In FIG. 5, the composition of the storage layer SL is denoted as “SL composition”, the presence or absence of a cobalt layer is denoted as “Co insert”, the thickness of the storage layer SL is denoted as “SL THK”, the anisotropy field of the storage layer SL is denoted as “SL Hk”, the saturation magnetization of the storage layer SL is denoted as “SL Ms”, the calculated value of the thermal stability Δ is denoted as “Δcal.”, and the annealing temperature is denoted as “Anneal temp.” The write error rate WER is relatively expressed using two classifications, “Good” and “Bad”. The annealing temperature, is relatively expressed using three classifications, “high”, “middle”, and “low”.

As shown in FIG. 6, the MTJ element of Comparative Examples 1 and 2 has a stacked structure in which a tunnel barrier layer TB, a storage layer SL, and an oxide layer RED are stacked in this order. The tunnel barrier layer TB is composed of a magnesium oxide (MgO). The storage layer SL is composed of cobalt iron boron (CoFeB). The oxide layer RED is composed of a rare-earth oxide, such as a gadolinium oxide. As shown in FIG. 6, annealing (a thermal treatment) is performed after a. plurality of layers are stacked. In actuality, annealing is performed after all the layers forming the MTJ element 10 are stacked. Annealing is similarly performed in the comparative examples shown in FIGS. 7-9.

In Comparative Examples 1 and 2 shown in FIG. 5, the anisotropy field Hk is low, and the saturation magnetization Ms is high. Also, in Comparative Examples 1 and 2, the WER deteriorates.

As shown in FIG. 7, the MTJ element of Comparative Example 3 has a stacked structure in which a tunnel barrier layer TB, a storage layer SL, and an oxide layer RED are stacked in this order. The tunnel barrier layer TB is composed of a magnesium oxide (MgO). The storage layer SL is composed of cobalt iron boron (CoFeB) to which molybdenum (Mo) is added as a non-magnetic element. The CoFeB added with. molybdenum (Mo) is denoted “CoFeB—Mo”. The oxide layer RED is composed of a rare-earth oxide, such as a gadolinium oxide.

In Comparative Example 3 shown in FIG. 5, since the non-magnetic element, molybdenum (Mo), is added to the ferromagnetic layer (CoFeB), the saturation magnetization Ms is decreased. Also, the WER improves. However, the thermal stability Δ deteriorates in Comparative Example 3.

As shown in FIG. 8, the MTJ element of Comparative Examples 4-6 has a stacked structure in which a tunnel barrier layer TB, a storage layer SL, and an oxide layer REQ are stacked in this order. The tunnel barrier layer TB is composed of a magnesium oxide (MgO). The storage layer SL is composed of cobalt iron boron (CoFeB) to which a rare-earth element RE is added. The CoFeB added with a rare-earth element RE is denoted as “CoFeB-RE”. The rare-earth element RE is, for example, gadolinium (Gd). The CoFeB added with gadolinium (Gd) is denoted as “CoFeB—Gd”.

As shown in FIG. 5, the annealing temperatures in Comparative Examples 4, 5 and 6 are high, middle, and low, respectively. In Comparative Examples 4-6, the saturation magnetization Ms is further decreased. However, the thermal stability Δ deteriorates as the annealing temperature is higher, namely, in the order of Comparative Examples 6, 5, and 4. From Comparative Examples 4-6, it can be seen that the deterioration of the thermal stability Δ (decrease in Hk) occurs due to the low temperature resistance (low Neel temperature) of CoFeB—Gd. There are cases where annealing is performed at a high temperature in the process of manufacturing MTJ elements. Even during such high-temperature annealing, it is desirable for the magnetic characteristics of the MTJ elements not to deteriorate.

As shown in FIG. 9, the MTJ element of Examples 1-3 has a stacked structure in which a tunnel barrier layer TB, a storage layer SL, a cobalt layer Co, and an oxide layer REO are stacked in this order. The tunnel barrier layer TB is composed of a magnesium oxide (MgO). The storage layer SL is composed of CoFeB—RE, such as CoFeB—Gd. The storage layer SL, the cobalt layer Co, and the oxide layer REO in Examples 1-3 respectively correspond to the storage layer 16, the cobalt layer 17, and the oxide layer 18 shown in FIG. 1.

As shown in FIG. 5, the thickness of the cobalt layer Co is varied in Examples 1-3. Specifically, the thicknesses of the cobalt layer Co in Examples 1, 2 and 3 are 0.1 nm, 0.2 nm, and 0.3 nm, respectively. It is desirable that the thickness of the cobalt layer Co is equal to or greater than 0.1 nm, and equal to or less than 0.3 nm. The thermal stability Δ improves by inserting the cobalt layer Co between the storage layer SL and the oxide layer REO. In addition, the thermal stability Δ improves as the thickness of the cobalt layer Co increases, namely, in the order of Examples 1, 2 and 3. From Examples 1-3, it can be seen that Hk improves as the thickness of the cobalt layer Co increases, resulting in improvement in the thermal stability Δ.

[4] Advantageous Effects of First Embodiment

According to the first embodiment, a magnetoresistive element (MTJ element) 10 includes: (1) a reference layer 14 having an invariable magnetization direction; (2) a tunnel barrier layer 15 provided on the reference layer 14; (3) a storage layer 16 provided on the tunnel barrier layer 15, having a variable magnetization direction, and containing a rare-earth element; (4) a magnetic layer 17 provided on the storage layer 16 and composed of cobalt; and (5) an oxide layer 18 provided on the magnetic layer 17 and containing a rare-earth element, as described above.

Thus, according to the first embodiment, the storage layer 16 is configured of a ferromagnetic layer to which a rare-earth element is added. Such a configuration reduces the saturation magnetization Ms of the storage layer 16. This in turn results in a decrease in the write error rate WER.

Moreover, the MTJ element 10 includes an oxide layer 18 containing a rare-earth element. The oxide layer 18 is capable of removing impurities from an amorphous ferromagnetic layer through an annealing process. This improves the crystalline orientation of the storage layer 16.

Furthermore, a cobalt layer 17 is inserted between the storage layer 16 and the oxide layer 18. By inserting the cobalt layer 17, the thermal stability Δ of the storage layer 16 improves.

That is, the storage layer 16 of the present embodiment is capable of suppressing deterioration of the thermal stability A, while reducing the saturation magnetization Ms. In addition, by inserting the cobalt layer 17, the anisotropy field Hk improves, achieving both reduction in the saturation magnetization Ms and improvement in the thermal stability Δ while maintaining the exchange stiffness constant Aex. This results in realization of a magnetoresistive element with an improved performance.

### Second Embodiment

The second embodiment is a configuration example of a magnetic memory device using the MTJ element 10 according to the first embodiment, namely, an MRAM.

FIG. 10 is a block diagram of an MRAM 100 according to the second embodiment. The MRAM 100 comprises a memory cell array 31, a row decoder 32, a column decoder 33, column selection circuits 34A and 34B, write circuits 35A and 35B, a read circuit 36, etc.

The memory cell array 31 includes a plurality of memory cells MC arranged in a matrix pattern. In the memory cell array 31, a plurality of bit lines BL, a plurality of source lines SL, and a plurality of word lines WL are provided. The bit lines EL and the source lines SL extend in the column direction, and the word lines WL extend in the row direction intersecting the column direction. Each memory cell MC is coupled to one of the bit lines BL, one of the source lines SL, and One of the word lines WL.

Each memory cell MC includes one MTJ element 10 and one selective transistor 30. The selective transistor 30 is composed of, for example, an n-channel MOS transistor.

One end of the MTJ element 10 is coupled to the bit line BL; the other end is coupled to the drain of the selective transistor 30. The source of the selective transistor 30 is coupled to the source line SL, and the gate of the selective transistor 30 is coupled to the word line WL.

The row decoder 32 is coupled to the word lines WL. The row decoder 32 decodes an address signal received from the outside, and selects one of the word lines WL based on the decoded result.

The column decoder 33 decodes the address signal received from the outside, and generates a column selection signal. The column selection signal is transmitted to the column selection circuits 34A and 34B.

The column selection circuit 34A is coupled to one set of ends of the bit lines BL and one set of ends of the source lines SL. The column selection circuit 34B is coupled to the other set of ends of the bit lines BL and the other set of ends of the source lines SL. The column selection circuits 34A and 34B select one of the bit lines EL and one of the source lines SL, based on the column selection signal transmitted from the column decoder 33.

The write circuit 35A is coupled to the one set of ends of the bit lines BL and the one set of ends of the source lines SL, via the column selection circuit 34A. The write circuit 35A is coupled to the other set of ends of the bit lines BL and the other set of ends of the source lines SL, via the column selection circuit 34A. The write circuits 35A and 35B allow a write current to flow through the memory cell MC, via the bit lines EL and the source lines SL, thereby writing data to the memory cell. The write circuits 35A and 35B include a source circuit, such as a current source or a voltage source that generates a write current, and a sink circuit that absorbs the write current.

The read circuit 36 is coupled to the bit line BL and the source line SL via the column selection circuit 34B. The read circuit 36 reads data stored in the selected memory cell by detecting a current flowing through the selected memory cell. The read circuit 36 includes, for example, a voltage source or a current source that generates a read current, a sense amplifier that detects and amplifies the read current, and a latch circuit that temporarily stores data.

When data is written, the write circuits 35A and 35B allow a write current to bi-directionally flow through the MTJ element 10 in the memory cell MC, according to the data written into the memory cell MC. That is, the write circuits 35A and 35B supply the memory cell MC with either a write current flowing from the bit lines BL to the source lines SL, or a write current flowing from the source lines SL to the bit lines EL, according to the data written into the MTJ element 10. The current value of the write current is set to be greater than the magnetization reversal threshold value.

When data is read, the read circuit 36 supplies the memory cell MC with a read current. The current value of the read current is set to be smaller than the magnetization reversal threshold value, in such a manner that the magnetization of the storage layer of the MTJ element 10 is not reversed by the read current.

The current value or the potential varies according to the magnitude of the resistance value of the MTJ element 10 to which the read current is supplied. The data stored in the MTJ element 10 is determined based on the amount of fluctuation (of a read signal or a read output) determined according to the magnitude of the resistance value.

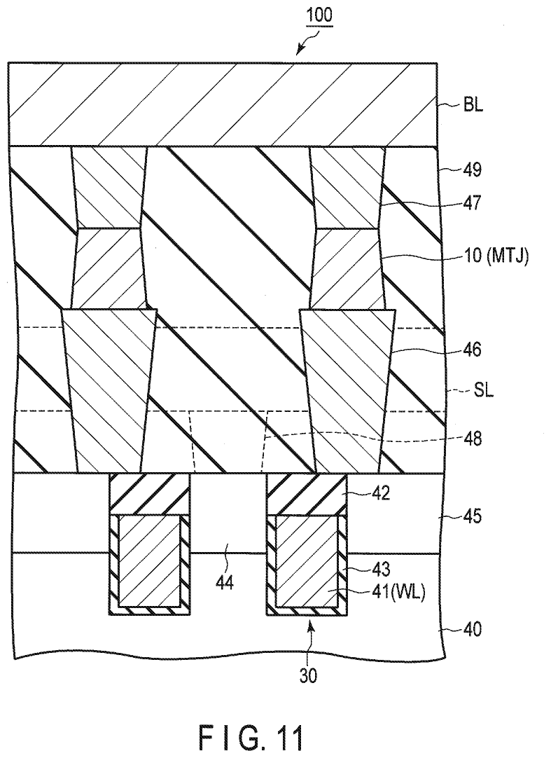

Next, a description will be given of an example of the structure of the MRAM. FIG. 11 is a cross-sectional view of the MRAM 100 according to the second embodiment.

The semiconductor substrate 40 is formed of a p-type semiconductor substrate. The p-type semiconductor substrate 40 may be a p-type semiconductor region (p-type well) provided in a semiconductor substrate.

A selective transistor 30 is provided in the semiconductor substrate 40. The selective transistor 30 is composed of, for example, an n-channel MOS transistor. The selective transistor 30 is composed of a MOS transistor having, for example, a buried-gate structure. The selective transistor 30 is not limited to a buried-gate-type MOS transistor, and may be formed of a planar MOS transistor.

The selective transistor 30 includes a gate electrode 41, a cap layer 42, a gate insulation film 43, a source region 44, and a drain region 45. The gate electrode 41 functions as a word line WL.

The gate electrode 41 extends in the row direction, and is buried in the semiconductor substrate 40. An upper surface of the gate electrode 41 is below an upper surface of the semiconductor substrate 40. The cap layer 42, composed of an insulating material, is provided on the gate electrode 41. The gate insulation film 43 is provided on the bottom surface and both side surfaces of the gate electrode 41. The source region 44 and the drain region 45 are provided on both sides of the gate electrode 41 inside the semiconductor substrate 40. The source region 44 and the drain region 45 are formed of an n+-type diffusion region, formed by introducing high-concentration n-type impurities into the semiconductor substrate 40.

A pillar-shaped lower electrode 46 is provided on the drain region 45, and an MTJ element 10 is provided on the lower electrode 46. A pillar-shaped upper electrode 47 is provided on the MTJ element 10. A bit line BL, extending in the column direction intersecting the row direction, is provided on the upper electrode 47.

A contact plug 48 is provided on the source region 44. A source line SL, extending in the column direction, is provided on the contact plug 48. For example, the source line SL is composed of an interconnect layer provided below the bit line BL. An interlayer insulation layer 49 is provided between the semiconductor substrate 40 and the bit line BL.

According to the second embodiment, an MRAM can be configured using the MTJ element 10 described in the first embodiment. Also, an MRAM with an improved performance can be realized.

In the above-described embodiments, a case has been described where a three-terminal selective transistor is applied as a switching element; however, a two-terminal switching element with a switching function may be applied as a switching element. In addition, the architecture of the memory cell array may be freely selected, such as an array architecture including a plurality of structures stacked in Z direction, each structure being capable of selecting one memory cell MC by a combination of one bit line BL and one word line WL.

The embodiments described above are presented merely as examples and are not intended to restrict the scope of the invention/present disclosure. These novel embodiments may be realized in various other forms, and various omissions, replacements, and changes can be made without departing from the gist of the invention/present disclosure. Such embodiments and modifications are included in the scope and gist of the invention/present disclosure, and are included in the scope of the invention/present disclosure described in the claims and its equivalents.

1. A magnetoresistive element comprising:
a first magnetic layer having an invariable magnetization direction;
a non-magnetic layer provided on the first magnetic layer;
a second magnetic layer provided on the non-magnetic layer, having an invariable magnetization direction, and containing a rare-earth element;
a third magnetic layer provided on the second magnetic layer and composed of cobalt; and
an oxide layer provided on the third magnetic layer.

2. The magnetoresistive element according to claim 1, wherein
the rare-earth element of the second magnetic layer includes scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), or lutetium (Lu).

3. The magnetoresistive element according to claim 1, wherein
the second magnetic layer contains at least one of iron (Fe), cobalt (Co), and nickel (Ni).

4. The magnetoresistive element according to claim 2, wherein
the second magnetic layer contains at least one of iron (Fe), cobalt (Co), and nickel (Ni).

5. The magnetoresistive element according to claim 1, wherein
the oxide layer contains a rare-earth element.

6. The magnetoresistive element according to claim 2, wherein
the oxide layer contains a rare-earth element.

7. The magnetoresistive element according to claim 3, wherein
the oxide layer contains a rare-earth element.

8. The magnetoresistive element according to claim 4, wherein
the oxide layer contains a rare-earth element.

9. The magnetoresistive element according to claim 4, wherein
the rare-earth element of the oxide layer includes scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), or lutetium (Lu).

10. The magnetoresistive element according to claim 1, wherein
the third magnetic layer has a thickness equal to or greater than 0.1 nm and equal to or smaller than 0.3 nm.

11. The magnetoresistive element according to claim 2, wherein
the third magnetic layer has a thickness equal to or greater than 0.1 nm and equal to or smaller than 0.3 nm.

12. The magnetoresistive element according to claim 3, wherein
the third magnetic layer has a thickness equal to or greater than 0.1 nm and equal to or smaller than 0.3 nm.

13. The magnetoresistive element according to claim 4, wherein
the third magnetic layer has a thickness equal to or greater than 0.1 nm and equal to or smaller than 0.3 nm.

14. The magnetoresistive element according to claim 5, wherein
the third magnetic layer has a thickness equal to or greater than 0.1 nm and equal to or smaller than 0.3 nm.

15. The magnetoresistive element according to claim 6, wherein
the third magnetic layer has a thickness equal to or greater than 0.1 nm and equal to or smaller than 0.3 nm.

16. The magnetoresistive element according to claim 7, wherein
the third magnetic layer has a thickness equal to or greater than 0.1 nm and equal to or smaller than 0.3 nm.

17. The. magnetoresistive element according to claim 8, wherein
the third magnetic layer has a thickness equal to or greater than 0.1 nm and equal to or smaller than 0.3 nm.

18. The magnetoresistive element according to claim 9, wherein
the third magnetic layer has a thickness equal to or greater than 0.1 nm and equal to or smaller than 0.3 nm.

19. A magnetic memory device comprising:
a memory cell including the magnetoresistive element according to claim 1.
